(19) United States
(12) Patent Application Publication
(10) Pub. No.: US 2006/0205149 A1
(43) Pub. Date: Sep. 14, 2006

(54) Method of fabricating flash memory device

(75) Inventors: Seung Cheol Lee, Icheon-Si (KR); Pil Geun Song, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-do (KR)

(21) Appl. No.: 11/151,016

(22) Filed: Jun. 13, 2005

(30) Foreign Application Priority Data
Mar. 9, 2005 (KR) 2005-19639

(51) Int. Cl. H01L 21/336

(52) U.S. Cl. 438/257; 438/264; 438/265

(57) ABSTRACT

A method of fabricating a flash memory device is disclosed which includes sequentially stacking a tunnel oxide film, a first conductive film, a dielectric film, a second conductive film and a metal silicide film on a semiconductor substrate, and patterning the metal silicide film, the second conductive film, the dielectric film, the first conductive film and the tunnel oxide film to form a stack gate electrode, performing a radical oxidization process on the entire resulting surface having the stack gate electrode, whereby the profile of the stack gate electrode before the radical oxidization process is performed is maintained while forming a sidewall oxide film on sidewalls of the stack gate electrode, and performing a thermal treatment process of a hydrogen atmosphere on the entire resulting surface on which the radical oxidization process is performed.

### BACKGROUND

1. Technical Field

Methods of fabricating flash memory devices are disclosed which result in improved charge retention characteristics and which avoid damage to the tunnel oxide and dielectric films during heat treatment of the source/drain region.

2. Discussion of Related Art

During the fabrication of a flash memory device, a stack gate is formed on a semiconductor substrate, and a re-oxidization process is then performed.

The re-oxidization process is performed to compensate for lateral damage of a tunnel oxide film during an etch process for forming a stack gate electrode pattern, and damage to a semiconductor substrate, which also happens during an etch process. A re-oxidization process can serve to mitigate damage of a semiconductor substrate to some degree when performing an ion implant process for forming source and drain regions, which is a subsequent process.

Furthermore, a re-oxidization process may be performed to improve charge retention characteristics being one of unique characteristics of a flash memory device. In the re-oxidization process, the flash memory device has a negative profile while sides are oxidized.

Accordingly, if a re-oxidization process is performed, sheet resistance (Rs) of a tungsten silicide film increases. The cell ratio also decreases due to variations in a thickness of a dielectric film (a dielectric film smiling phenomenon) at the sides, which is generated while the dielectric film is oxidized.

A capacitance value of the dielectric film also decreases due to the reduced cell ratio, which degrades the electrical characteristics of the device. That is, the charge retention characteristics and reliability as well as program and device characteristics are degraded.

Therefore, there is a need for improved flash memory manufacturing technologies which can improve charge retention characteristics of a flash memory device and which can prevent a smiling phenomenon of a tunnel oxide film and a dielectric film, which are generated after a re-oxidization process and a thermal treatment process of a source/drain region.

### SUMMARY OF THE DISCLOSURE

A method of fabricating a flash memory device is disclosed which can improve charge retention characteristics of the flash memory device and prevent a smiling phenomenon of a tunnel oxide film and a dielectric film, which are generated after a thermal treatment process of a source/drain region.

A disclosed method of fabricating a flash memory device having a stack gate electrode comprises: performing a radical oxidization process on the entire resulting surface having the stack gate electrode, whereby the profile of the stack gate electrode before the radical oxidization process is performed is maintained while forming a sidewall oxide film on sidewalls of the stack gate electrode.

The radical oxidization process can include depositing radicals, such as H+, OH and O−, on the sidewalls of the stack gate electrode pattern by generating the radicals.

The radical oxidization process is preferably performed in process conditions including a process time of from about 10 minutes to about 5 hours, a temperature in a range of from about 850 to 1050° C., a H₂ gas flow atmosphere in a range of from about 300 to about 600 sccm, a O₂ gas flow atmosphere in a range of from about 1500 to about 2500 sccm, a pressure in a range of from about 38 to about 42 Pa, e.g., about 40.3 Pa, and a temperature climb rate and a decline rate in a range of from about 5 to about 100° C./sec.

The sidewall oxide film can be formed to a thickness in a range of from about 80 to about 100 Å.

A pressure in the process conditions in which the radical oxidization process is preferably performed to maximize generation of the radicals.

The method can further comprise performing a thermal treatment process of a hydrogen atmosphere after performing the radical oxidization process.

The stack gate electrode can be formed by a stack of a tunnel oxide film, a first conductive film, a dielectric film, a second conductive film and a metal silicide film.

Another disclosed method of fabricating a flash memory device having a stack gate electrode, comprises: sequentially stacking a tunnel oxide film, a first conductive film, a dielectric film, a second conductive film and a metal silicide film on a semiconductor substrate; patterning the metal silicide film, the second conductive film, the dielectric film, the first conductive film and the tunnel oxide film to form a stack gate electrode; performing a radical oxidization process on the entire resulting surface having the stack gate electrode, whereby the profile of the stack gate electrode before the radical oxidization process is performed is maintained while forming a sidewall oxide film on sidewalls of the stack gate electrode; and performing a thermal treatment process of a hydrogen atmosphere on the entire resulting surface on which the radical oxidization process has been performed.

The radical oxidization process can include depositing radicals, such as H+, OH and O−, on the sidewalls of the stack gate electrode pattern by generating the radicals.

The radical oxidization process can be performed in process conditions including a process time in a range of from about 10 minutes to about 5 hours, a temperature in a range of from about 850 to about 1050° C., a H₂ gas flow atmosphere in a range of from about 300 to about 600 sccm, a O₂ gas flow atmosphere in a range of from about 1500 to about 2500 sccm, a pressure in a range of from about 38 to about 42 Pa, e.g., about 40.3 Pa, and a temperature climb rate and a decline rate in a range of from about 5 to about 100° C./sec.

The sidewall oxide film is preferably formed to a thickness in a range of from about 80 to about 100 Å.

A pressure in the process conditions in which the radical oxidization process is preferably performed to maximize generation of the radicals.

### BRIEF DESCRIPTION OF THE DRAWINGS

FIGS. 1 and 2 are cross-sectional views for explaining a disclosed method of fabricating a flash memory device.

### DETAILED DESCRIPTION OF PREFERRED EMBODIMENTS

Where it is described below that one film is “on” the other film or a semiconductor substrate, the one film may directly contact the other film or the semiconductor substrate. Or, one or more films may be disposed between the one film and the other film or the semiconductor substrate. Furthermore, in the drawing, the thickness and size of each layer are not to scale and may be exaggerated for convenience of explanation and clarity. Like reference numerals are used to identify the same or similar parts.

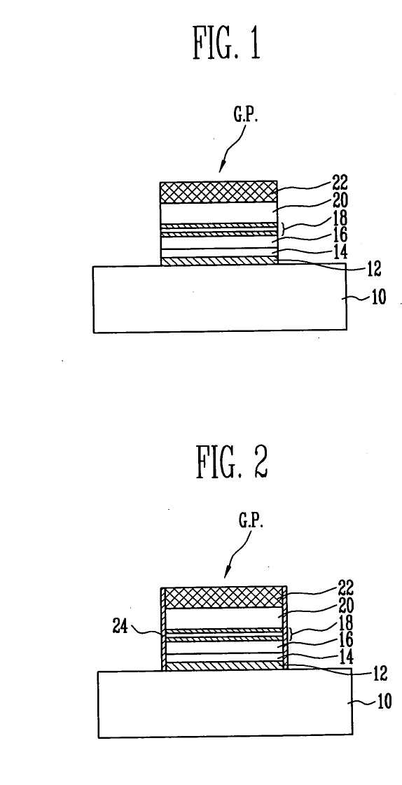

FIGS. 1 and 2 are cross-sectional views for explaining a disclosed method of fabricating a flash memory device.

Referring to FIG. 1, a tunnel oxide film 12 and a first polysilicon film 14 for floating gate electrode are sequentially formed on a semiconductor substrate 10.

At this time, the semiconductor substrate 10 is divided into a PMOS region and a NMOS region. A well region (not shown) and a region (not shown) into which an ion for threshold voltage control is implanted are formed in the PMOS region, and a well region (not shown) and a region (not shown) into which an ion for threshold voltage control is implanted are formed in the NMOS region, through an ion implant process.

The tunnel oxide film 12 can be performed by performing wet oxidization at a temperature of about 750 to about 800° C., and then performing thermal treatment at a temperature of about 900 to about 910° C. under a gas atmosphere of N₂ for about 20 to about 30 minutes.

The first polysilicon film 14 for floating gate electrode can be formed by means of a low pressure chemical vapor deposition (hereinafter, referred to as “LP-CVD”) method using a Si source gas such as SiH₄ or SiH₆ at a temperature in a range of from about 480 to about 550° C. and a pressure of from about 0.1 to about 3 torr.

After a pad nitride film (not shown) is formed on the first polysilicon film 14, a photoresist pattern (not shown) is formed.

The pad nitride film (not shown), the first polysilicon film 14, the tunnel oxide film 12 and a predetermined depth of the semiconductor substrate 10 are etched using the pattern as an etch mask, thereby forming trenches (not shown) that define element isolation regions. Thereafter, after the trenches (not shown) are filled with a high density plasma (HDP) oxide film having good gap fill characteristics, a polishing process such as chemical mechanical polishing (CMP) is performed until the pad nitride film (not shown) is exposed, thus forming the element isolation films (not shown). The pad nitride film (not shown) is then stripped by means of an etch process.

Thereafter, a second polysilicon film 16 for a floating gate electrode, a dielectric film 18, a third polysilicon film 20 for control gate electrode, and a metal silicide film 22 are sequentially formed on the resulting surface.

The second polysilicon film 16 can be formed by performing a LP-CVD method using a Si source gas, such as SiH₄ or SiH₆, and a PH₃ gas at a temperature from about 480 to about 550° C. and a pressure from about 0.1 to about 3 torr, and then flowing a PH₃ source gas from about 100 to about 200 sccm while flowing a SiH₄ gas from about 500 to about 1500 sccm.

The dielectric film 18 preferably has an ONO structure, i.e., a structure in which a first oxide film, a nitride film and a second oxide film are sequentially stacked. At this time, the first oxide film and the second oxide film can be formed to a thickness from about 35 to about 60 Å by means of a LP-CVD method at a temperature from about 600 to about 700° C., a pressure from about 1 to about 3 torr, and can be formed using a high temperature oxide (HTO) film using SiH₂Cl₂ (dichlorosilane, DCS) as a source or a HTO film using or N₂O gas as a source. The nitride film can be formed to a thickness from about 50 to about 65 Å by means of a LP-CVD method using NH₃ and SiH₂Cl₂ gas as a reactor material at a pressure from about 1 to about 3 torr and a temperature from about 650 to about 800° C.

The third polysilicon film 20 for control gate electrode can be formed to a thickness from about 700 to about 1500 Å by means of a LP-CVD method using a Si source gas such as SiH₄ or SiH₆ and a PH₃ gas a temperature from about 500 to about 550° C. and a pressure from about 0.1 to about 3 torr.

The metal silicide film 22 is formed to a thickness from about 1000 to 1200 Å using a tungsten silicide film through reaction of SiH₄ (monosilane: MS) or SiH₂Cl₂ (dichlorosilane: DCS) and WF₆. At this time, stoichiometry is controlled to from about 2.0 to about 2.8 in order to minimize sheet resistance of the film quality.

Thereafter, after a photoresist pattern (not shown) is formed on the resulting surface, an etch process is performed using the pattern as an etch mask, thereby forming a stack type gate electrode pattern (G.P).

Referring to FIG. 2, a radical oxidization process being a re-oxidization process is performed on the resulting surface in which the stack type gate electrode pattern (G.P) is formed, thus forming a sidewall oxide film 24. A thermal process of hydrogen atmosphere is then performed on the entire resulting surface.

If the radical oxidization process is performed, radicals such as H+, OH and O− are generated. The generated radicals are deposited on the sidewalls of the stack gate electrode pattern (G.P) to form the sidewall oxide film 24. A thermal process of hydrogen atmosphere is then performed on the entire resulting surface having the formed sidewall oxide film 24.

A thermal treatment process of a prior art re-oxidization process and a thermal treatment process that is performed after formation of a source/drain region generate a smiling phenomenon of a tunnel oxide film and a dielectric film since the thermal treatment processes are performed for a long time period. Accordingly, the disclosed radical oxidization process using the radicals such as H+, OH and O− has a process time relatively shorter than that of other processes. Thus, the smiling phenomenon of a tunnel oxide film and an ONO film, which is caused by an oxidization process for a long time, can be minimized using the disclosed techniques.

Furthermore, if the profile of the stack gate electrode is maintained by performing the radical oxidization process as above, the coupling ratio can be increased and a thickness of the oxide film formed in the stack gate electrode can become regular.

In addition, if the thermal process of the hydrogen atmosphere is performed on the entire resulting surface having the sidewall oxide film 24 formed by the radical oxidization process, dangling bonds that are broken in the etch process for forming the gate electrode pattern can be protected. If the dangling bonds are protected as such, charge retention and reliability characteristics can be improved.

The radical oxidization process can be performed in process conditions including a process time of from about 10 minutes to about 5 hours, a temperature of from about 850 to about 1050° C., a H₂ gas flow atmosphere of from about 300 to about 600 sccm, a O₂ gas flow atmosphere of from about 1500 to about 2500 sccm, a pressure of from about 38 to about 42 Pa, e.g., about 40.3 Pa, and a temperature climb rate and a decline rate of from about 5 to about 100° C./sec.

The sidewall oxide film 24 that is formed after the radical oxidization process and the thermal treatment process of the hydrogen atmosphere is formed to a thickness of from about 80 to about 100 Å.

If a pressure in the process conditions in which the radical oxidization process is performed is 1/2000 lower than that in an existing wet or dry oxidization method, generation of radicals such as H+, OH and O− is maximized.

It is preferred that a N2 gas is not used in the radical oxidization process.

Though not shown in the drawings, an ion implant process is performed on the resulting surface in which the sidewall oxide film 24 is formed, thus forming a source/drain region (not shown) at a predetermined region of the semiconductor substrate. Thereafter, after a source/drain region formation process, a thermal treatment process is performed so as to improve charge retention characteristics.

A sidewall oxide film is formed through a radical oxidization process even in the thermal treatment process performed after the source/drain region formation process. It is thus possible to prevent a smiling phenomenon of the tunnel oxide film and the ONO film.

A smiling phenomenon of the tunnel oxide film and the ONO film, which is caused by the oxidization process for a long time period, can also be minimized.

Furthermore, as described above, if the profile of the stack gate electrode is maintained by performing the radical oxidization process as above, the coupling ratio can be increased, and a thickness of the oxide film formed in the stack gate electrode can become regular.

Furthermore, if the thermal process of the hydrogen atmosphere is performed on the entire resulting surface having the sidewall oxide film formed by the radical oxidization process, dangling bonds that are broken in the etch process for forming the gate electrode pattern can be protected. If the dangling bonds are protected as such, charge retention and reliability characteristics can be improved.

As described above, a sidewall oxide film is formed through a radical oxidization process even in a thermal treatment process performed after a source/drain region formation process. Accordingly, there is an effect in that a smiling phenomenon of a tunnel oxide film and an ONO film can be prevented.

Furthermore, if a thermal process of a hydrogen atmosphere is performed on the entire resulting surface having a sidewall oxide film formed by a radical oxidization process, dangling bonds that are broken in an etch process for forming a gate electrode pattern can be protected. Therefore, there is an effect in that charge retention and reliability characteristics can be improved since dangling bonds are protected.

Although the foregoing description has been made with reference to the preferred embodiments, it is to be understood that changes and modifications to the disclosed methods may be made by one of ordinary skill in the art without departing from the spirit and scope of this disclosure and the appended claims.

What is claimed is:

1. A method of fabricating a flash memory device having a stack gate electrode, the method comprising:
performing a radical oxidization process on the entire surface including the stack gate electrode, whereby a profile of the stack gate electrode before the radical oxidization process is performed is maintained while forming a sidewall oxide film on sidewalls of the stack gate electrode.

2. The method as claimed in claim 1, wherein the radical oxidization process includes depositing H+, OH and O− radicals on the sidewalls of the stack gate electrode pattern.

3. The method as claimed in claim 1, wherein the radical oxidization process is performed under process conditions including a process time in a range of from about 10 minutes to about 5 hours, a temperature in a range of from about 850 to 1050° C., a H₂ gas flow in a range of from about 300 to about 600 sccm, a O₂ gas flow in a range of from about 1500 to about 2500 sccm, a pressure in a range of from about 38 to about 42 Pa and a temperature climb rate and a decline rate in a range of from about 5 to about 100° C./sec.

4. The method as claimed in claim 1, wherein the sidewall oxide film is formed to a thickness in a range of from about 80 to about 100 Å.

5. The method as claimed in claim 3, wherein the pressure of the radical oxidization process is 40.3 Pa.

6. The method as claimed in claim 1, further comprising performing a thermal treatment process under a hydrogen atmosphere after performing the radical oxidization process.

7. The method as claimed in claim 1, wherein the stack gate electrode is a stack of a tunnel oxide film, a first conductive film, a dielectric film, a second conductive film and a metal silicide film.

8. A method of fabricating a flash memory device having a stack gate electrode, the method comprising:
sequentially stacking a tunnel oxide film, a first conductive film, a dielectric film, a second conductive film and a metal silicide film on a semiconductor substrate;
patterning the metal silicide film, the second conductive film, the dielectric film, the first conductive film and the tunnel oxide film to form a stack gate electrode;
performing a radical oxidization process on the entire resulting surface having the stack gate electrode, whereby the profile of the stack gate electrode before the radical oxidization process is performed is maintained while forming a sidewall oxide film on sidewalls of the stack gate electrode; and
performing a thermal treatment process of a hydrogen atmosphere on the entire resulting surface on which the radical oxidization process is performed.

9. The method as claimed in claim 8, wherein the radical oxidization process includes depositing H+, OH and O− radicals on sidewalls of the stack gate electrode pattern.

10. The method as claimed in claim 8, wherein the radical oxidization process is performed under process conditions including a process time in a range of from about 10 minutes to about 5 hours, a temperature in a range of from about 850 to 1050° C., a H₂ gas flow in a range of from about 300 to about 600 sccm, a O₂ gas flow in a range of from about 1500 to about 2500 sccm, a pressure in a range of from about 38 to about 42 Pa and a temperature climb rate and a decline rate in a range of from about 5 to about 100° C./sec.

11. The method as claimed in claim 8, wherein the sidewall oxide film is formed to a thickness in a range of from about 80 to about 100 Å.

12. The method as claimed in claim 10, wherein the pressure of the radical oxidization process is 40.3 Pa.
